(19) United States
(12) Patent Application Publication
(10) Pub. No.: US 2009/0121279 A1
(43) Pub. Date: May 14, 2009

(54) SEMICONDUCTOR DEVICE AND METHOD OF MANUFACTURING THE SAME

(76) Inventors: Hirokazu Ishida, Yokohama-shi (JP); Takashi Suzuki, Yokkaichi-shi (JP); Yoshio Ozawa, Yokohama-shi (JP); Ichiro Mizushima, Yokohama-shi (JP); Yoshitaka Tsunashima, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/249,354

(22) Filed: Oct. 10, 2008

(30) Foreign Application Priority Data
Oct. 12, 2007 (JP) 2007-266811

(51) Int. Cl. H01L 21/20; H01L 29/786

(52) U.S. Cl. 257/324; 438/479; 257/E29.285; 257/E21.133

(57) ABSTRACT

A semiconductor device includes a single crystal silicon substrate an insulating layer partially formed on the single crystal silicon substrate, a single crystal silicon layer formed on the single crystal silicon substrate and the insulating layer, and containing a defect layer resulting from an excessive group IV element, and a plurality of first gate structures for memory cells, each including a first gate insulating film formed on the single crystal silicon layer, a charge storage layer formed on the first gate insulating film, a second gate insulating film formed on the charge storage layer, and a control gate electrode formed on the second gate insulating film.

### CROSS-REFERENCE TO RELATED APPLICATIONS

This application is based upon and claims the benefit of priority from prior Japanese Patent Application No. 2007-266811, filed Oct. 12, 2007, the entire contents of which are incorporated herein by reference.

### BACKGROUND OF THE INVENTION

1. Field of the Invention

The present invention relates to a semiconductor device and a method of manufacturing the same.

2. Description of the Related Art

Recently, the following technique has been proposed (e.g., see Jpn. Pat. Appln. KOKAI Publication No. 2006-73939). According to the technique, a nonvolatile semiconductor memory device is manufactured using a silicon on insulator (SOI) substrate.

However, the nonvolatile semiconductor memory device using the SOI substrate has the following problem. Specifically, a single crystal silicon layer functioning as a channel region is formed on an insulating layer. Therefore, in an erase operation of a memory cell, carriers are stored in the single crystal silicon layer. This is a factor of varying memory cell characteristic.

### BRIEF SUMMARY OF THE INVENTION

A first aspect of the present invention, there is provided a semiconductor device comprising: a single crystal silicon substrate: an insulating layer partially formed on the single crystal silicon substrate; a single crystal silicon layer formed on the single crystal silicon substrate and the insulating layer, and containing a defect layer resulting from an excessive group IV element; and a plurality of first gate structures for memory cells, each including a first gate insulating film formed on the single crystal silicon layer, a charge storage layer formed on the first gate insulating film, a second gate insulating film formed on the charge storage layer, and a control gate electrode formed on the second gate insulating film.

A second aspect of the present invention, there is provided a method of manufacturing a semiconductor device, comprising: partially forming an insulating layer on a single crystal silicon substrate; forming an amorphous silicon layer on the single crystal silicon substrate and the insulating layer; implanting a group IV element to the amorphous silicon layer; annealing the amorphous silicon layer to which the group IV element is implanted, thereby forming a single crystal silicon layer containing a defect layer resulting from the group IV element; forming a first gate insulating film on the single crystal silicon layer; forming a charge storage layer on the first gate insulating film; forming a second gate insulating film on the charge storage layer; and forming a control gate electrode on the second gate insulating film.

A third aspect of the present invention, there is provided a method of manufacturing a semiconductor device, comprising: partially forming an insulating layer on a single crystal silicon substrate; forming an amorphous silicon layer on the single crystal silicon substrate and the insulating layer; implanting a group IV element to the amorphous silicon layer; annealing the amorphous silicon layer to which the group IV element is implanted, thereby forming a preliminary single crystal silicon layer; repeating implanting a group IV element to the preliminary single crystal silicon layer and annealing the preliminary single crystal silicon layer to which the group IV element is implanted one time or more, thereby forming a single crystal silicon layer containing a defect layer resulting from the group IV element; forming a first gate insulating film on the single crystal silicon layer; forming a charge storage layer on the first gate insulating film; forming a second gate insulating film on the charge storage layer; and forming a control gate electrode on the second gate insulating film.

### BRIEF DESCRIPTION OF THE SEVERAL VIEWS OF THE DRAWING

FIGS. 1A to 1C are views schematically showing part of a method of manufacturing a semiconductor device according to a first embodiment of the present invention;

FIGS. 2A to 2C are views schematically showing part of a method of manufacturing a semiconductor device according to a first embodiment of the present invention;

FIGS. 3A to 3C are views schematically showing part of a method of manufacturing a semiconductor device according to a first embodiment of the present invention;

FIGS. 4A to 4C are views schematically showing part of a method of manufacturing a semiconductor device according to a first embodiment of the present invention;

FIGS. 5A to 5C are views schematically showing part of a method of manufacturing a semiconductor device according to a first embodiment of the present invention;

FIGS. 6A to 6C are views schematically showing part of a method of manufacturing a semiconductor device according to a first embodiment of the present invention;

FIG. 7A and FIG. 7B are cross-sectional views schematically showing part of a method of manufacturing a semiconductor device according to a first embodiment of the present invention;

FIG. 8A and FIG. 8B are cross-sectional views schematically showing the structure of a semiconductor device according to a modification example of a first embodiment of the present invention;

FIG. 9 is a cross-sectional view schematically showing part of a method of manufacturing a semiconductor device according to a modification example of a first embodiment of the present invention;

FIG. 10A and FIG. 10B are cross-sectional views schematically showing the structure of a semiconductor device according to a second embodiment of the present invention;

FIGS. 11A to 11C are views schematically showing part of a method of manufacturing a semiconductor device according to a second embodiment of the present invention;

FIG. 12A and FIG. 12B are cross-sectional views schematically showing the structure of a semiconductor device according to a modification example of a second embodiment of the present invention;

FIG. 13A and FIG. 13B are cross-sectional views schematically showing the structure of a semiconductor device according to a third embodiment of the present invention;

FIGS. 14A to 14C are views schematically showing part of a method of manufacturing a semiconductor device according to a third embodiment of the present invention;

FIG. 15A and FIG. 15B are cross-sectional views schematically showing the structure of a semiconductor device according to a modification example of a third embodiment of the present invention;

FIG. 16A and FIG. 16B are cross-sectional views schematically showing the structure of a semiconductor device according to a fourth embodiment of the present invention;

FIGS. 17A to 17C are views schematically showing part of a method of manufacturing a semiconductor device according to a fourth embodiment of the present invention;

FIG. 18A and FIG. 18B are cross-sectional views schematically showing the structure of a semiconductor device according to a modification example of a fourth embodiment of the present invention;

FIG. 19A and FIG. 19B are cross-sectional views schematically showing the structure of a semiconductor device according to a fifth embodiment of the present invention;

FIGS. 20A to 20C are views schematically showing part of a method of manufacturing a semiconductor device according to a fifth embodiment of the present invention; and

FIG. 21A and FIG. 21B are cross-sectional views schematically showing the structure of a semiconductor device according to a modification example of a fifth embodiment of the present invention.

### DETAILED DESCRIPTION OF THE INVENTION

Various embodiments of the present invention will be hereinafter described with reference to the accompanying drawings. In the following embodiments, a nonvolatile semiconductor memory device such as NAND flash memory using silicon on insulator (SOI) technique will be described as a semiconductor device.

### Embodiment 1

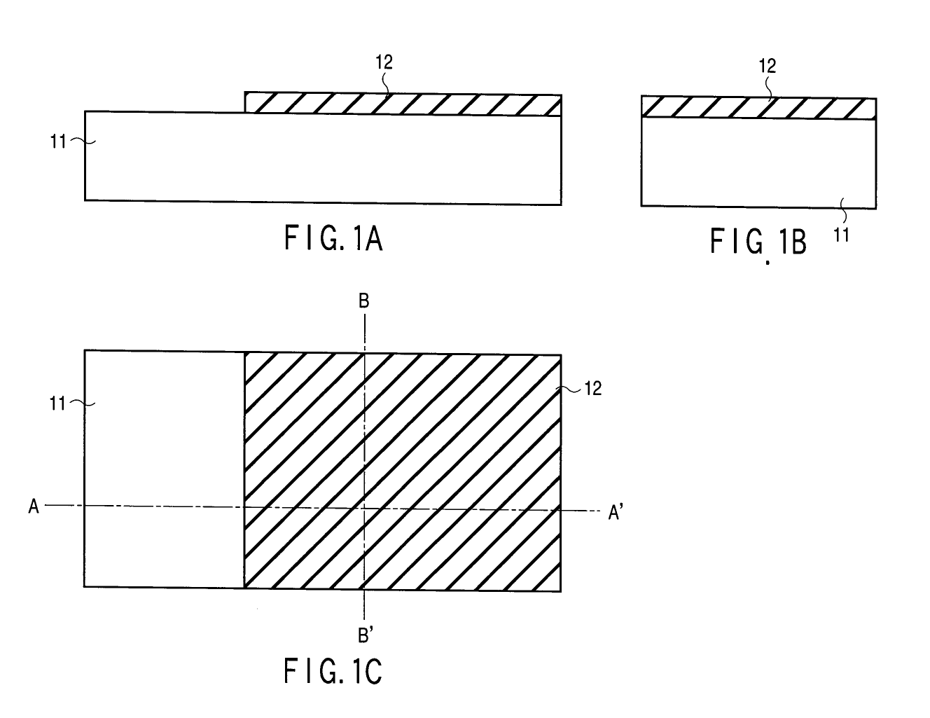

FIGS. 1A to 1C to FIGS. 7A and 7B are views schematically showing a method of manufacturing a semiconductor device according to a first embodiment. FIG. 1A to FIG. 7A is a cross-sectional view in a bit line direction. FIG. 1B to FIG. 7B is a cross-sectional view in a word line direction. FIG. 1C to FIG. 6C is a plan view. FIG. 1A to FIG. 6A corresponds to a cross section taken along the line A-A′ shown in FIG. 1C to FIG. 6C. FIG. 1B to FIG. 6B corresponds to a cross section taken along the line B-B′ shown in FIG. 1C to FIG. 6C.

As shown in FIGS. 1A to 1C, an insulating layer 12 is formed on a p-type single crystal silicon substrate 11. Specifically, a silicon oxide film having a thickness of 50 nm is formed as the insulating layer 12. Then, the insulating layer 12 is patterned using a photo resist pattern (not shown) as a mask. In this way, the insulating layer 12 is partially formed on the single crystal silicon substrate 11 and a part of the substrate 11 is exposed.

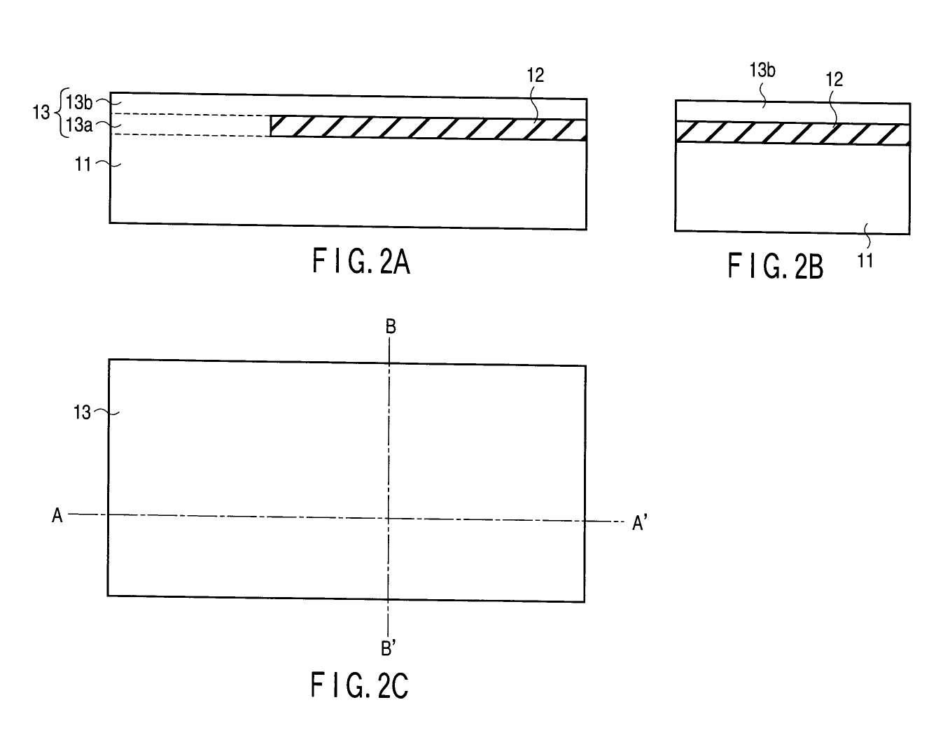

As illustrated in FIGS. 2A to 2C, an amorphous silicon layer 13a is formed on the entire surface by chemical vapor deposition (CVD). Thereafter, chemical mechanical polishing (CMP) is carried out with respect to the amorphous silicon layer 13a using the insulating layer 12 as a stopper. In this way, the amorphous silicon layer 13a on the insulating layer 12 is removed so that the amorphous silicon layer 13a on the single crystal silicon substrate 11 remains. In this case, the upper surface of the insulating layer 12 is flushed with the upper surface of the amorphous silicon layer 13a remaining on the single crystal silicon substrate 11. Then, an amorphous silicon layer 13b having a thickness of 50 nm is formed on the entire surface by CVD. As a result, an amorphous silicon layer 13 comprising the amorphous silicon layers 13a and 13b is formed on the single crystal silicon substrate 11 and the insulating layer 12.

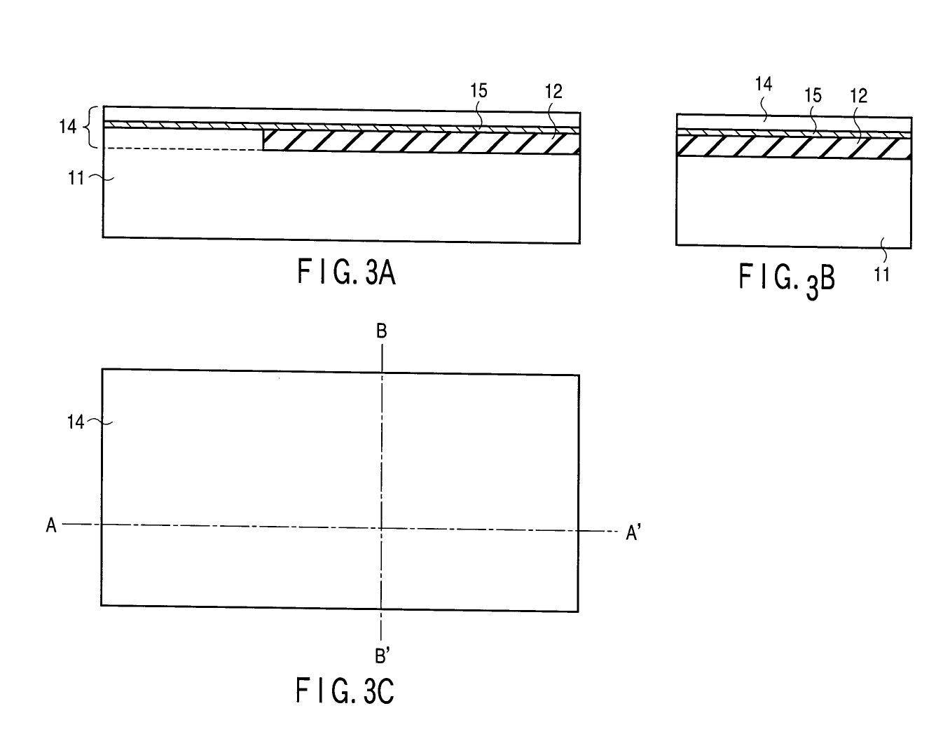

As depicted in FIGS. 3A to 3C, silicon (Si) is implanted as a group IV element into the amorphous silicon layer 13. Specifically, silicon ions are implanted under the conditions that implantation energy is 50 eV and dose is 5×10¹⁵ cm⁻². The concentration distribution peak position of the implanted silicon atom may be shallower or deeper than the interface between the insulating layer 12 and the amorphous silicon layer 13. In addition, the concentration distribution peak may be positioned in the vicinity of the interface between the insulating layer 12 and the amorphous silicon layer 13. According to this embodiment, silicon (Si) is used as the group IV element to be implanted into the amorphous silicon layer 13. In this case, other group IV elements such as germanium (Ge) may be used.

Then, the amorphous silicon layer 13 into which silicon ion is implanted is annealed. Specifically, annealing is carried out at a temperature of about 600° C. and for about three hours. A single crystal silicon layer 14 including a defect layer 15 based on ion-implanted silicon (group IV element) is formed on the single crystal silicon substrate 11 and the insulating layer 12. In other words, the amorphous silicon layer 13 is converted to the single crystal silicon layer 14 by solid-phase growth of the amorphous silicon layer 13. The defect layer 15 contains excessive silicon (group IV element). Thus, the defect layer 15 has higher silicon density (group IV element density) as compared with the peripheral single crystal silicon layer 14. The defect layer 15 has carrier generation-recombination center. Thus, this serves to solve the problem that carriers are stored in the single crystal silicon layer 14 in an erase operation of a memory cell, as described later.

The amorphous silicon layer 13 contains micro crystal grain generated when the amorphous silicon layer 13 is formed. If the amorphous silicon layer 13 is annealed without implanting silicon ions, the crystal growth of micro crystal grains advance; as a result, a polysilicon layer is formed. According to this embodiment, silicon ions are implanted into the amorphous silicon layer 13; therefore, micro crystal grains can be destroyed. As a result, according to this embodiment, poly-crystallization is prevented; therefore, it is possible to form a single crystal silicon layer 14 having a good quality. In addition, according to this embodiment, excessive silicon is implanted; therefore, this serves to reduce stress generated in crystallization. Therefore, from such circumstances, it is possible to form a single crystal silicon layer 14 having a good quality. Incidentally, the single crystal silicon layer 14 may be other forms so long as it basically has a single crystal structure. The whole of the single crystal silicon layer 14 does not necessarily a single crystal. For example, it may be that a non-single crystal region partially exists slightly in the single crystal silicon layer 14.

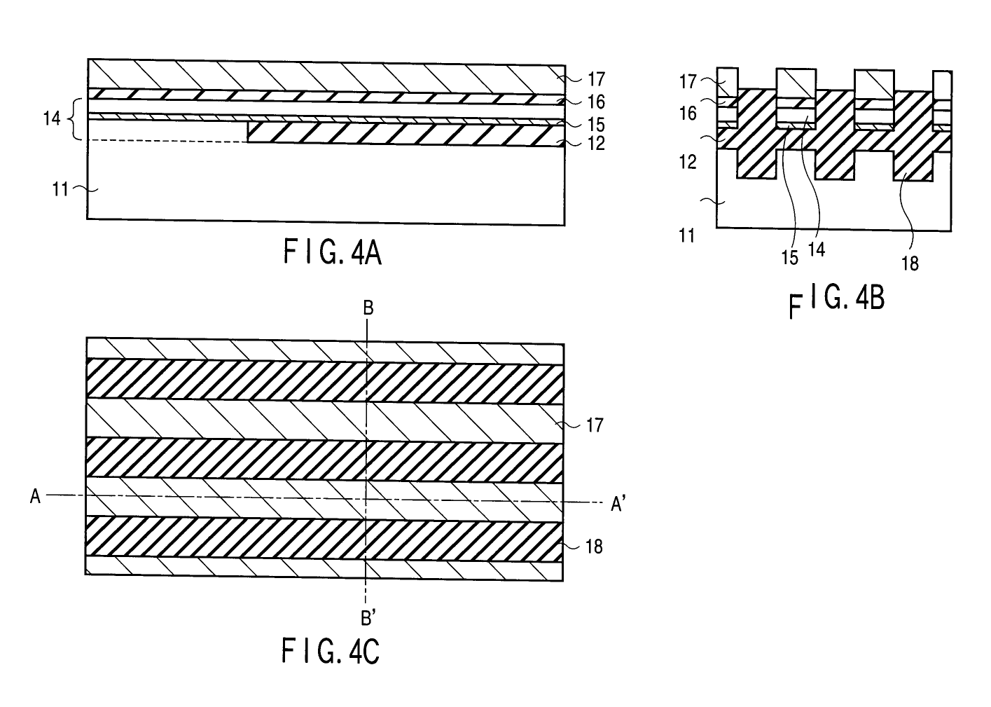

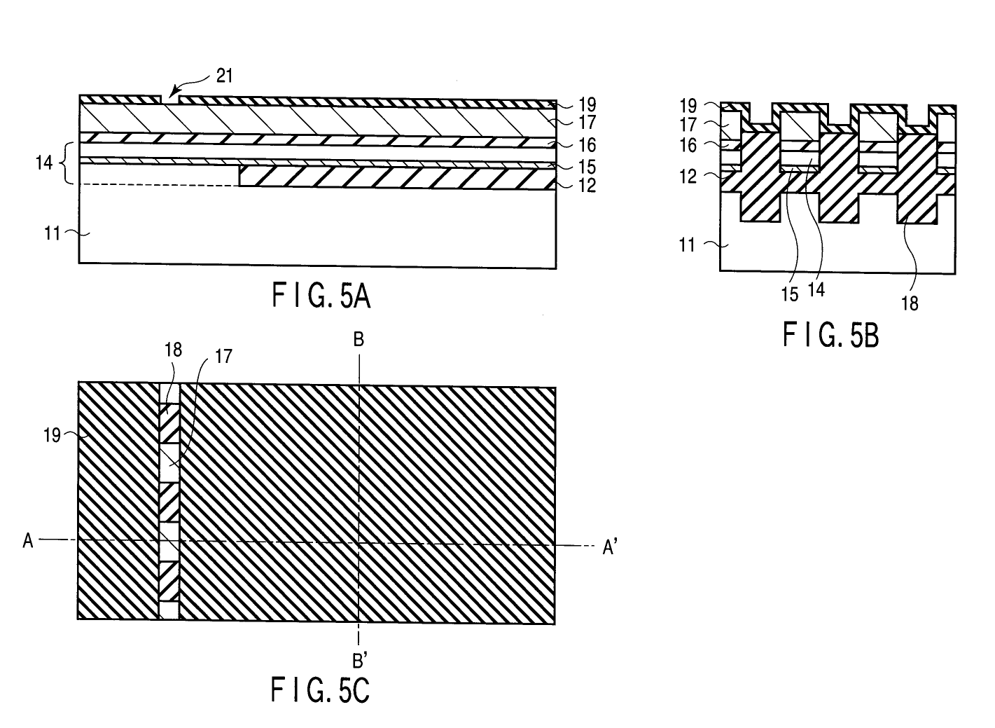

As seen from FIGS. 4A to 4C, a tunnel insulating film (first gate insulating film) 16 is formed on the single crystal silicon layer 14. Specifically, a silicon oxide film having a thickness of about 7 nm is formed as the tunnel insulating film 16 via thermal oxidization. Thereafter, a floating gate electrode film (charge storage layer) 17 is formed on the tunnel insulating film 16. Specifically, a phosphorous doped polysilicon film having a thickness of about 50 nm is formed as the floating gate electrode film 17 via a CVD process.

A photo resist pattern (not shown) is formed on the floating gate electrode film 17 via photolithography. The photo resist pattern is used for forming an isolation pattern, and has a plurality of patterns extending to a bit line direction. Thereafter, the foregoing floating gate electrode film 17, tunnel insulating film 16, single crystal silicon layer 14, insulating layer 12 and single crystal silicon substrate 11 are etched using the photo resist pattern as a mask via reactive ion etching (RIE). The foregoing etching is carried out, and thereby, an isolation trench is formed.

Then, the isolation trench is filled with a coating insulating film to form an isolation region 18. Specifically, a polysilazane film is coated so that the isolation trench is filled, and thereafter, the polysilazane film is converted to a silicon oxide film via vapor oxidization. In this way, a coating insulating film for isolation is formed. Incidentally, when the isolation trench is formed, crystal defect is generated in the surface of the trench. In order to repair the crystal defect, thermal or radical oxidization may be carried out before or after the coating insulating film is formed. In order to improve the insulation of the isolation region, a CVD insulating film and the coating insulating film may be combined to form the isolation region.

As shown in FIGS. 5A to 5C, an inter-electrode insulating film (second gate insulating film) 19 is formed on the floating gate electrode film 17. Specifically, an aluminum oxide film (alumina film) having a thickness of about 15 nm is formed as the inter-electrode insulating film 19 via atomic layer deposition (ALD). Thereafter, a slit 21 is formed in the inter-electrode insulating film 19 using a photo resist pattern (not shown) as a mask to expose a part of the floating gate electrode film 17. For example, a slit 21 having a width of 50 nm is formed via RIE.

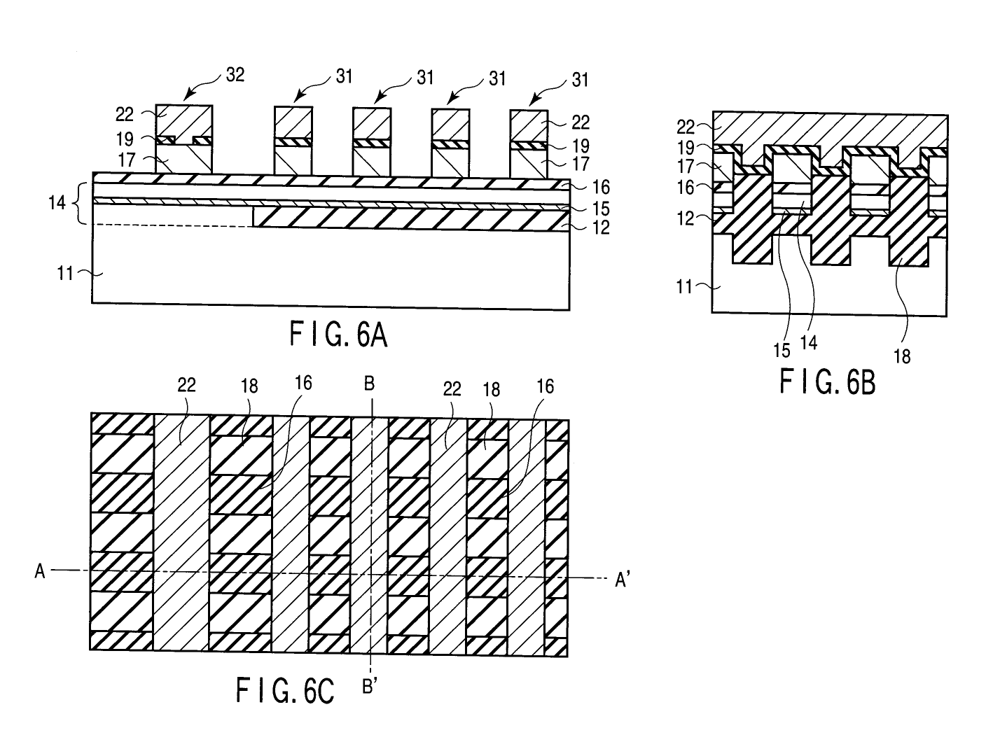

As illustrated in FIGS. 6A to 6C, a control gate electrode film 22 is formed on the entire surface. Specifically, a tungsten silicide film (WSi film) is formed using sputtering. In this case, the floating gate electrode film 17 and the control gate electrode film 22 are connected via the slit 21. Thereafter, a photo resist pattern (not shown) is formed on the control gate electrode film 22 via photolithography. The photo resist pattern has a plurality of patterns extending to a word line direction. Then, the foregoing control gate electrode film 22, inter-electrode insulating film 19 and floating gate electrode film 17 are etched using the photo resist pattern as a mask via RIE.

The foregoing etching is carried out, and thereby, a first gate structure 31 for a memory cell and a second gate structure 32 for a select transistor adjacent to the first gate structure are obtained. More specifically, the first gate structure 31 for a memory cell comprises the tunnel insulating film (first gate insulating film) 16, the floating gate electrode (charge storage layer) 17, the inter-electrode insulating film (second gate insulating film) 19 and the control gate electrode 22. The second gate structure 32 for a select transistor comprises a gate insulating film formed of the tunnel insulating film 16 and a gate electrode formed by the floating gate electrode film 17 and the control gate electrode film 22 connected. In addition, by the foregoing etching, a word line formed of the control gate electrode film 22 is obtained.

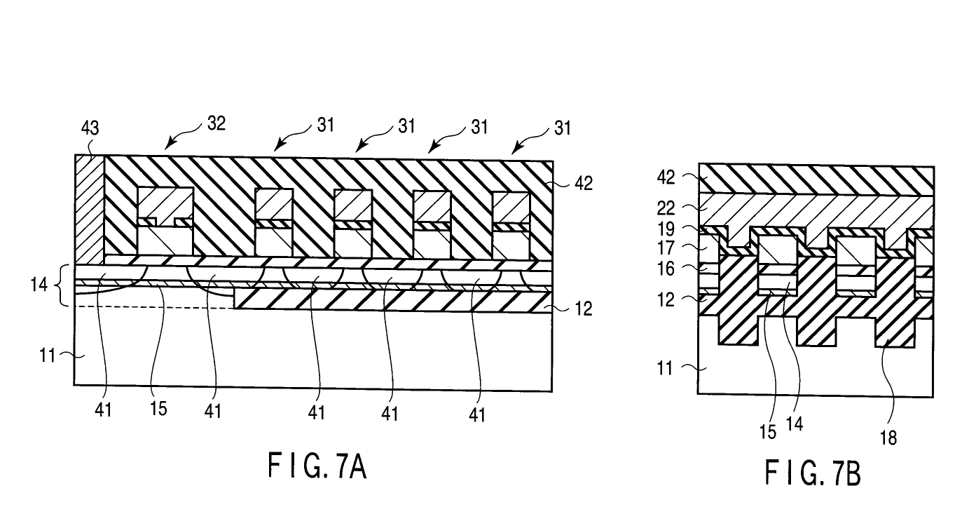

As depicted in FIGS. 7A and 7B, an n-type impurity diffusion layer 41 functioning as a source/drain region is formed in the single crystal silicon layer 14 via ion implantation and thermal diffusion. Thereafter, an interlayer insulating film 42 is formed using a CVD process. The interlayer insulating film 42 covers the first gate structure 31 for a memory cell and the second gate structure 32 for a select transistor. Then, the interlayer insulating film 42 is formed with a contact hole, which reaches the impurity diffusion layer 41 for a select transistor. The contact hole is filled with a conductor such as tungsten to form a contact (bit line contact, source line contact) 43.

Although the process after that is not illustrated, a NAND flash memory is completed via an interconnection process. In other words, it is possible to obtain a NAND nonvolatile memory having a structure in which a plurality of series-connected memory cells is provided between the select transistors.

As described above, according to this embodiment, the single crystal silicon layer 14 contains the defect layer 15 resulting from excessive silicon (group IV element). The defect layer 15 has carrier generation-recombination center. Thus, in an erase operation of a memory cell, it is possible to extinguish carriers (electrons or holes) transferred from the floating gate electrode 17 to the single crystal silicon layer 14 by generation-recombination center. This serves to prevent carries from being stored in the single crystal silicon layer 14. As a result, it is possible to prevent memory cell characteristic from being varied, and thus, to obtain a nonvolatile semiconductor memory device, which is excellent in reliability. In particular, carriers are easy to be stored in the SOI region formed with the single crystal silicon layer 14 on the insulating layer 12. However, the defect layer 15 is formed, and thereby, it is possible to effectively extinguish carriers.

As already described, the peak position of concentration distribution of the ion-implanted silicon atom (group IV element) is not specially limited. The peak position of concentration distribution may be shallower or deeper than the interface between the insulating layer 12 and the single crystal silicon layer 14. So long as the defect layer 15 resulting from ion-implanted silicon atom is formed in the single crystal silicon layer 14, it is possible to prevent carries from being stored in the single crystal silicon layer 14 by generation-recombination center based on the defect layer 15.

According to this embodiment, the insulating layer 12 is formed under the first gate structure 31 for a memory cell, but is not formed under the second gate structure 32 for a select transistor. In other words, the memory cell is formed at an SOI region, but the select transistor is formed at a non-SOI region. In the non-SOI region, the single crystal silicon layer 14 is directly formed on the single crystal silicon substrate 11. Thus, the single crystal silicon layer 14 having excellent crystallinity is obtained. As a result, it is possible to reduce junction leakage, and to improve select transistor characteristic. Therefore, as is evident from the above description, a nonvolatile semiconductor memory device having excellent reliability is obtained.

In addition, according to this embodiment, silicon (group IV element) ions are implanted to the amorphous silicon layer 13. Thus, this serves to destroy micro crystal grains contained in the amorphous silicon layer 13. Therefore, it is possible to prevent poly-crystallization when the amorphous silicon layer 13 is annealed, and to form the single crystal silicon layer 14 having a good quality. According to this embodiment, excessive silicon (group IV element) ions are implanted to the amorphous silicon layer 13. This serves to reduce stress generated in crystallization, and thus, to form the single crystal silicon layer 14 having a good quality.

According to the foregoing embodiment, the silicon (group IV element) ion implantation process and the annealing process are carried out by one time. However, these processes may be repeated several times. Specifically, the following process may be repeated more than one time, after annealing the amorphous silicon layer to which group IV element is implanted to form a preliminary single crystal silicon layer. One is a process of implanting group IV element to the preliminary single crystal silicon layer. Another is a process of annealing the preliminary single crystal silicon layer. As described above, the ion implantation process and the annealing process are repeated, and thereby, it is possible to obtain a high-quality single crystal silicon layer having uniform crystal orientation.

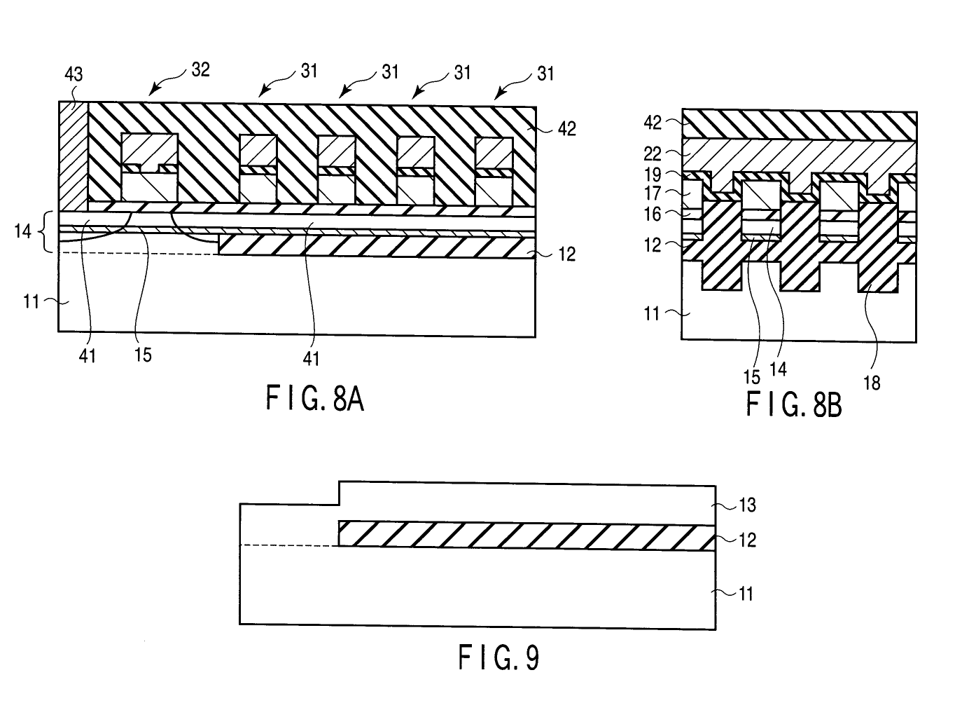

According to the foregoing embodiment, as shown in FIG. 7A and FIG. 7B, the impurity diffusion layers 41 are separated from each other. As illustrated in FIG. 8A and FIG. 8B, the impurity diffusion layers 41 may be continuously connected. Even if the foregoing structure is provided, the same effect as above is obtained. A nonvolatile semiconductor memory device having the foregoing depletion structure is disclosed in Jpn. Pat. Appln. KOKAI Publication No. 2006-73939.

According to the foregoing embodiment, the surface of the amorphous silicon layer 13 is planarized in the process of FIGS. 2A to 2C. In this case, the surface of the amorphous silicon layer 13 may not be planarized. Specifically, as depicted in FIG. 9, a step may be formed based on the insulating layer 12 at the boundary between the SOI region and the non-SOI region.

### Embodiment 2

A second embodiment of the present invention will be hereinafter described. The structure and the manufacturing method are basically the same as the first embodiment. Therefore, the matters described in the first embodiment are omitted.

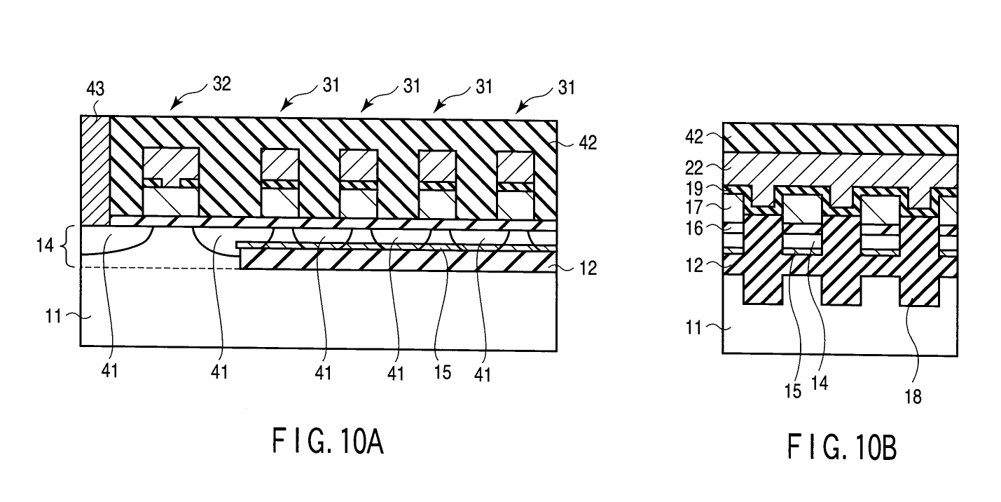

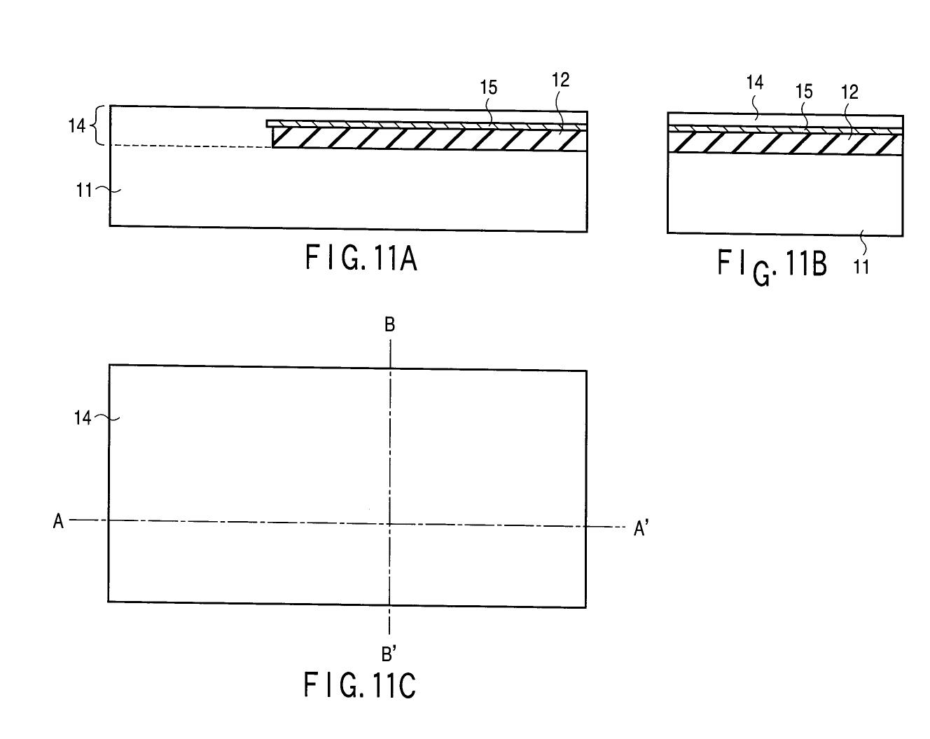

FIG. 10A and FIG. 10B are cross-sectional views schematically showing the structure of a semiconductor device according to a second embodiment. FIG. 11A is a cross-sectional view in a bit line direction. FIG. 10B is a cross-sectional view in a word line direction. The same reference numerals are used to designate the components corresponding to those described in the first embodiment, and their details are omitted.

According to the first embodiment, the SOI and non-SOI regions are formed with the defect layer 15 resulting from excessive group IV element. According to this second embodiment, as shown in FIG. 11A and FIG. 10B, the non-SOI region is not substantially formed with the defect layer 15 resulting from excessive group IV element. Thus, no defect layer is formed under the second gate structure 32 for a select transistor. Therefore, it is possible to prevent characteristic reduction (e.g., increase of junction leakage) of the select transistor resulting from the defect layer 15, and to form a select transistor having excellent characteristic.

FIGS. 11A to 11C are views showing part of a method of manufacturing the semiconductor device shown in FIG. 10A and FIG. 10B. FIG. 11A is a cross-sectional view in a bit line direction. FIG. 11B is a cross-sectional view in a word line direction. FIG. 11C is a plan view. FIG. 11A corresponds to a cross section taken along the line A-A′ of FIG. 11C. FIG. 11B corresponds to a cross section taken along the line B-B′ of FIG. 11C.

According to this embodiment, the process of FIGS. 2A to 2C of the first embodiment is made, and thereafter, a photo resist pattern (not shown) covering a non-SOI region is formed on an amorphous silicon layer 13 (see FIGS. 2A to 2C). Then, silicon (Si) ions are implanted as group IV element to the amorphous silicon layer 13 using the photo resist pattern as a mask. The ion implantation condition is the same as the first embodiment. The amorphous silicon layer 13 to which silicon is implanted is annealed at a temperature of about 600° C. for about three hours. In this way, as seen from FIGS. 11A to 11C, a single crystal silicon layer 14 containing a defect layer 15 resulting from implanted excessive silicon ions (group IV element) is formed.

According to this embodiment, the defect layer 15 is formed by implanting group IV element ion like the first embodiment. Thus, the same effect as the first embodiment is obtained. In addition, no defect layer is formed under the second gate structure 32 for a select transistor. Thus, it is possible to prevent characteristic reduction of the select transistor resulting from the defect layer 15, and thus, to form a select transistor having excellent characteristic.

According to the foregoing embodiment, the whole of the non-SOI region is not formed with the defect layer 15. A part of the non-SOI region may be formed with the defect layer 15 so long as the defect layer is not formed in a select transistor forming region. In also the case, the same effect as above is obtained.

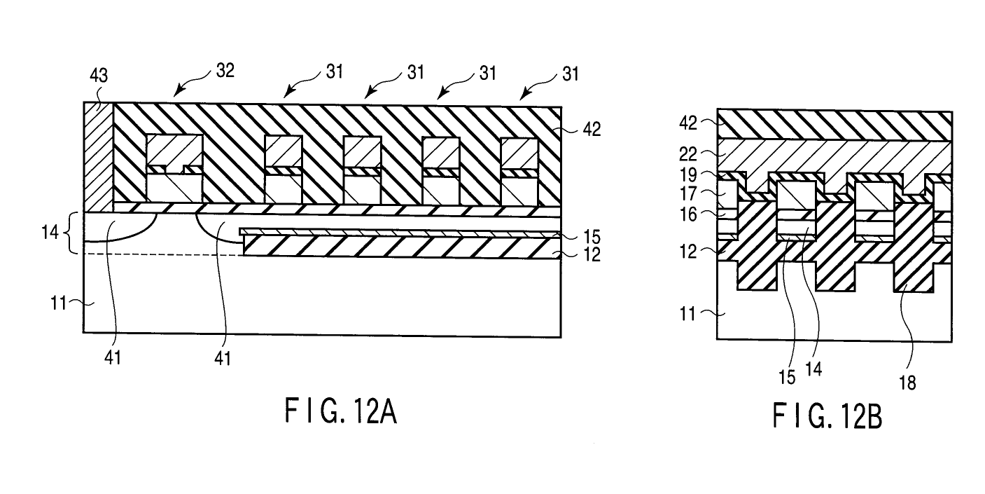

In this embodiment, an impurity diffusion layer 41 may be continuously connected as shown in FIG. 12A and FIG. 12B like the structure shown in FIG. 8A and FIG. 8B of the first embodiment. Even if the foregoing structure is provided, the same effect as above is obtained.

### Embodiment 3

A third embodiment of the present invention will be hereinafter described. The structure and the manufacturing method are basically the same as the first embodiment. Therefore, the matters described in the first embodiment are omitted.

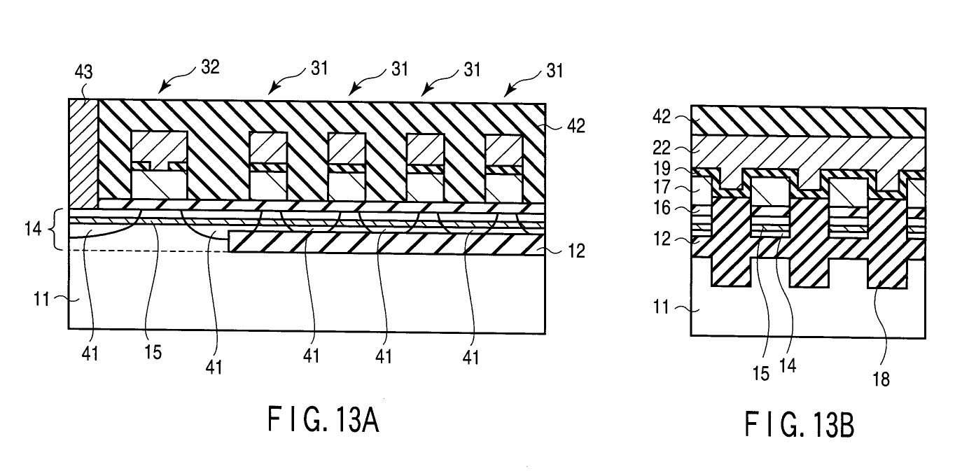

FIG. 13A and FIG. 13B are cross-sectional views schematically showing the structure of a semiconductor device according to a third embodiment. FIG. 13A is a cross-sectional view in a bit line direction. FIG. 13B is a cross-sectional view in a word line direction. The same reference numerals are used to designate the components corresponding to those described in the first embodiment, and their details are omitted.

According to the first embodiment, silicon (Si) ions are implanted as group IV element to form the defect layer 15. According to this embodiment, germanium (Ge) ions are implanted as group IV element. As described above, the germanium ion is implanted, and thereby, a silicon germanium layer (SiGe layer) is formed as the defect layer 15. The SiGe layer is formed, and thereby, stress is generated in channel regions for a memory cell transistor and a select transistor (i.e., strain is given to the channel region). As a result, the mobility of transistors is improved, and thus, it is possible to form a memory cell transistor and a select transistor having excellent characteristic.

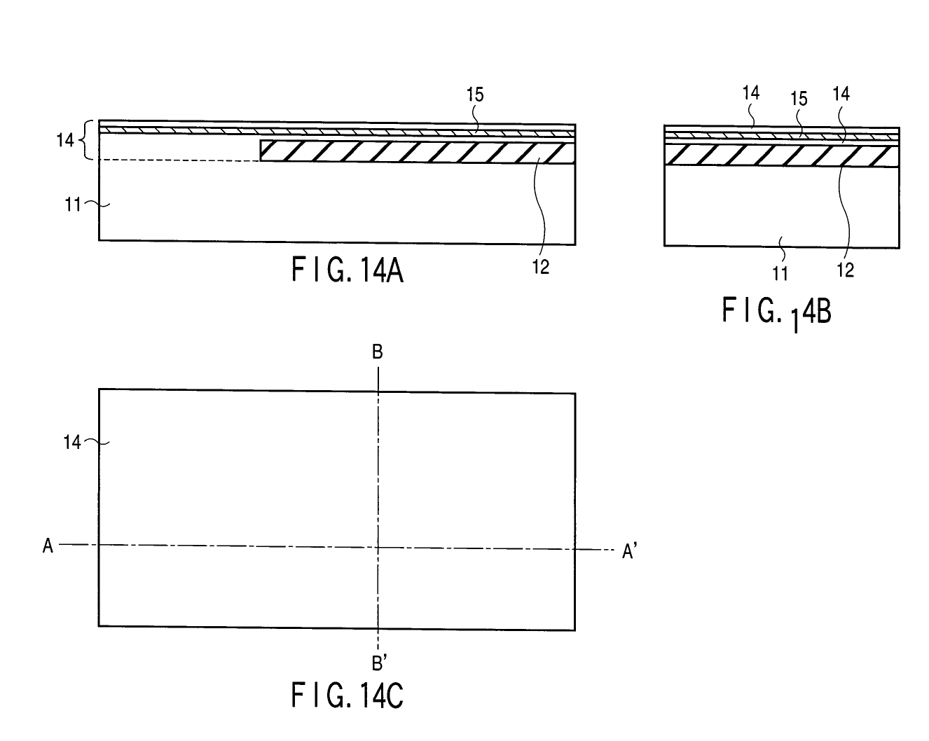

FIGS. 14A to 14C are views showing part of a method of manufacturing the semiconductor device shown in FIG. 13A and FIG. 13B. FIG. 14A is a cross-sectional view in a bit line direction. FIG. 14B is a cross-sectional view in a word line direction. FIG. 14C is a plan view. FIG. 14A corresponds to a cross section taken along the line A-A′ of FIG. 14C. FIG. 14B corresponds to a cross section taken along the line B-B′ of FIG. 14C.

According to this embodiment, germanium (Ge) is implanted as group IV element to the amorphous silicon layer 13 (see FIGS. 2A to 2C) after the process of FIGS. 2A to 2C in the first embodiment. In this case, ion implantation conditions are set considering the following matter. Specifically, the peak position of concentration distribution of ion-implanted germanium atom is positioned shallower than the interface between the insulating layer 12 and the amorphous silicon layer 13. The amorphous silicon layer 13 to which germanium ion is implanted is annealed at a temperature of about 600° C. for about three hours. As seen from FIGS. 14A to 14C, a single crystal silicon layer 14 is formed containing the silicon germanium layer (SiGe layer) as the defect layer 15 resulting from ion-implanted excessive germanium. The silicon germanium layer 15 is formed at a position shallower than the interface between the insulating layer 12 and the single crystal silicon layer 14.

According to this embodiment, the defect layer 15 is formed by implanting group IV element ion like the first embodiment. Thus, the same effect as the first embodiment is obtained. In addition, according to this embodiment, the silicon germanium layer (SiGe layer) is formed as the defect layer 15. Thus, stress is generated in a channel region of a transistor. Therefore, this serves to improve the mobility of a transistor, and to form a memory cell transistor and a select transistor having excellent characteristic.

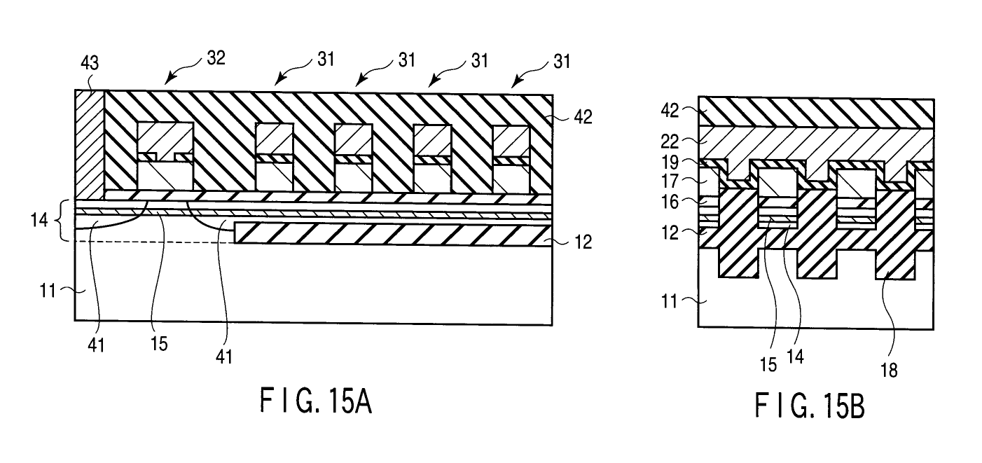

In this embodiment, an impurity diffusion layer 41 may be continuously connected as shown in FIG. 15A and FIG. 15B like the structure shown in FIG. 8A and FIG. 8B of the first embodiment. Even if the foregoing structure is provided, the same effect as above is obtained.

### Embodiment 4

A fourth embodiment of the present invention will be hereinafter described. The structure and the manufacturing method are basically the same as the first embodiment. Therefore, the matters described in the first embodiment are omitted.

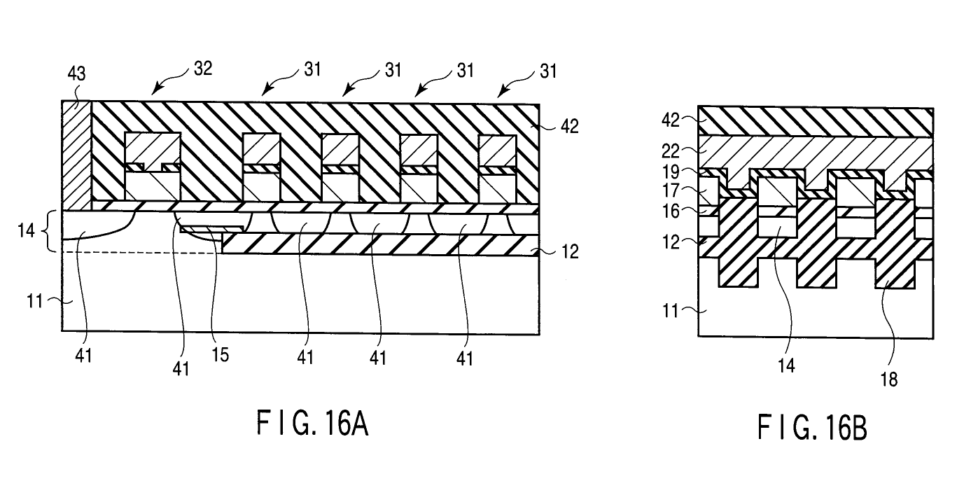

FIG. 16A and FIG. 16B are cross-sectional views schematically showing the structure of a semiconductor device according to a fourth embodiment. FIG. 16A is a cross-sectional view in a bit line direction. FIG. 16B is a cross-sectional view in a word line direction. The same reference numerals are used to designate the components corresponding to those described in the first embodiment, and their details are omitted.

According to the fourth embodiment, a defect layer 15 is formed at a region only between a memory cell forming region and a select transistor forming region. In an erase operation of a memory cell, an electric field becomes the highest at the region between a memory cell forming region and a select transistor forming region. According to this embodiment, such a high-field generation region is provided with the defect layer 15 having carrier generation-recombination center. Thus, in an erase operation of a memory cell, carriers (electrons) transferred from the floating gate electrode film 17 to the single crystal silicon layer 14 is effectively extinguished by generation-recombination center of the defect layer 15. In addition, the defect layer 15 is not formed under the first gate structure 31 for a memory cell and the second gate structure 32 for a select transistor. Therefore, it is possible to prevent characteristic reduction of the memory cell transistor and the select transistor resulting from the defect layer 15.

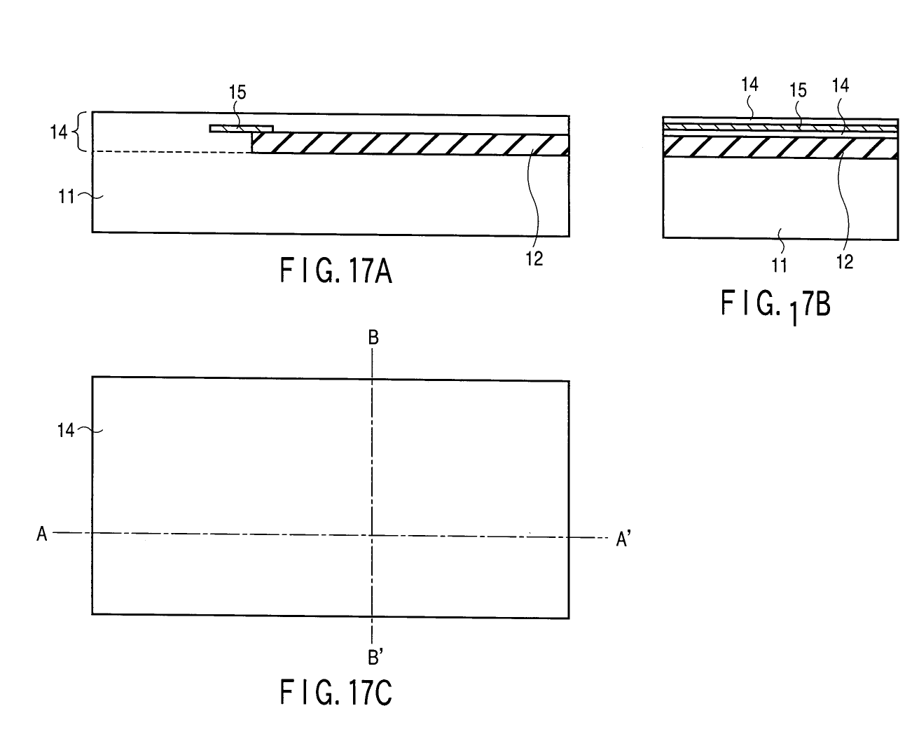

FIGS. 17A to 17C are views showing part of a method of manufacturing the semiconductor device shown in FIG. 16A and FIG. 16B. FIG. 17A is a cross-sectional view in a bit line direction. FIG. 17B is a cross-sectional view in a word line direction. FIG. 17C is a plan view. FIG. 17A corresponds to a cross section taken along the line A-A′ of FIG. 17C. FIG. 17B corresponds to a cross section taken along the line B-B′ of FIG. 17C.

According to this embodiment, a photo resist pattern (not shown) covering only a forming region of the defect layer 15 is formed on the amorphous silicon layer 13 (see FIG. 2) after the process of FIGS. 2A to 2C in the first embodiment. Thereafter, silicon (Si) ions are implanted as group IV element to the amorphous silicon layer 13 using the photo resist pattern as a mask. The ion implantation condition is the same as the first embodiment. The amorphous silicon layer 13 to which silicon is implanted is annealed at a temperature of about 600° C. for about three hours. In this way, as seen from FIGS. 17A to 17C, a single crystal silicon layer 14 containing a defect layer 15 resulting from implanted excessive silicon ions (group IV element) is formed.

According to this embodiment, group IV element ion is implanted to form the defect layer 15 like the first embodiment; therefore, the same effect as the first embodiment is obtained. In particular, according to this embodiment, the highest field region in an erase operation of a memory cell is provided with the defect layer 15. Thus, it is possible to effectively extinguish carriers (electrons) transferred from the floating gate electrode film 17 to the single crystal silicon layer 14 by generation-recombination center of the defect layer 15 in an erase operation of a memory cell. As a result, this serves to prevent carriers from being stored in the single crystal silicon layer 14, and thus, to prevent memory cell characteristic from varying. In addition, according to this embodiment, the defect layer 15 is not formed under the first gate structure 31 for a memory cell and the second gate structure 32 for a select transistor. As a result, it is possible to prevent characteristic reduction of memory cell and select transistors based on the defect layer 15. Therefore, according to this embodiment, it is possible to prevent memory cell characteristic from varying by carrier storage. In addition, it is possible to prevent characteristic reduction of memory cell and select transistors, and thus, to obtain a nonvolatile semiconductor memory device, which is excellent in characteristic and reliability.

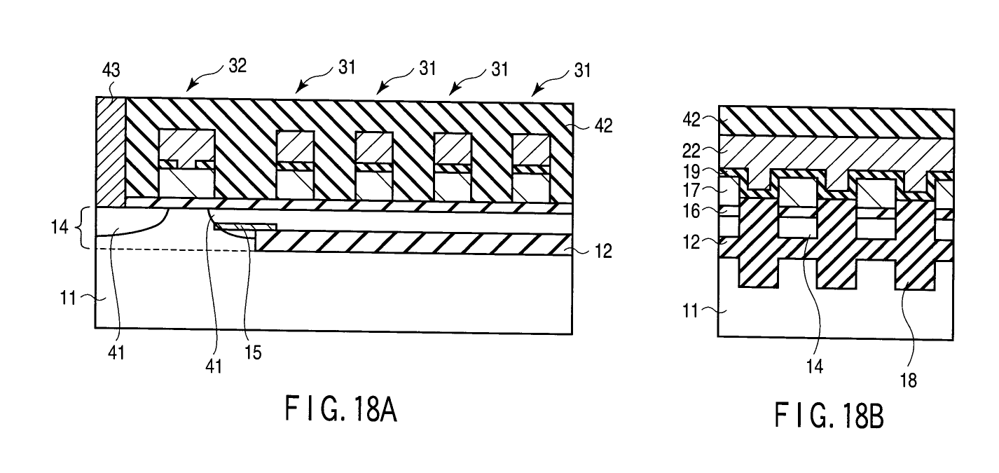

In this embodiment, an impurity diffusion layer 41 may be continuously connected as shown in FIG. 18A and FIG. 18B like the structure shown in FIG. 8A and FIG. 8B of the first embodiment. Even if the foregoing structure is provided, the same effect as above is obtained.

### Embodiment 5

A fifth embodiment of the present invention will be hereinafter described. The structure and the manufacturing method are basically the same as the first embodiment. Therefore, the matters described in the first embodiment are omitted.

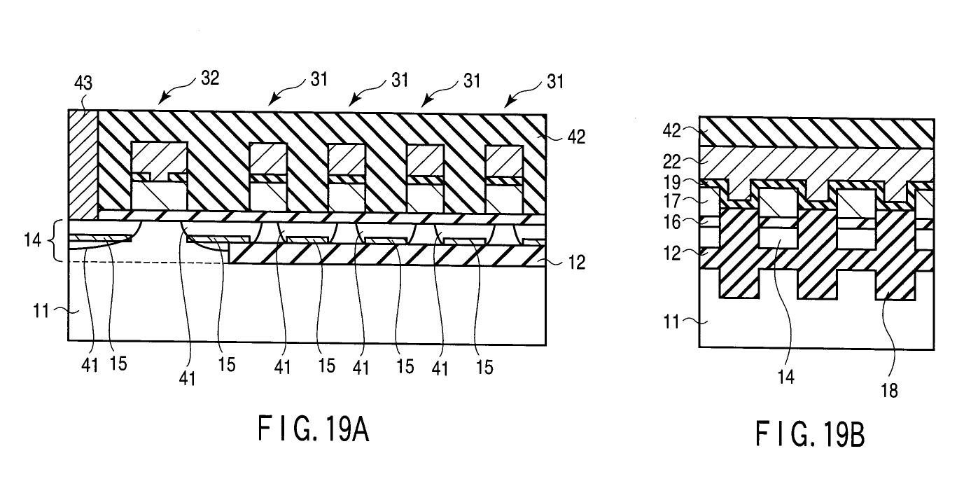

FIG. 19A and FIG. 19B are cross-sectional views schematically showing the structure of a semiconductor device according to a fifth embodiment. FIG. 19A is a cross-sectional view in a bit line direction. FIG. 19B is a cross-sectional view in a word line direction. The same reference numerals are used to designate the components corresponding to those described in the first embodiment, and their details are omitted.

According to the fifth embodiment, as shown in FIG. 19A and FIG. 19B, a defect layer 15 is formed only at a region between a memory cell forming region and a select transistor forming region and region between adjacent select transistor forming regions. In other words, according to this embodiment, the defect layer 15 is not formed under the first gate structure 31 for a memory cell and the second gate structure 32 for a select transistor.

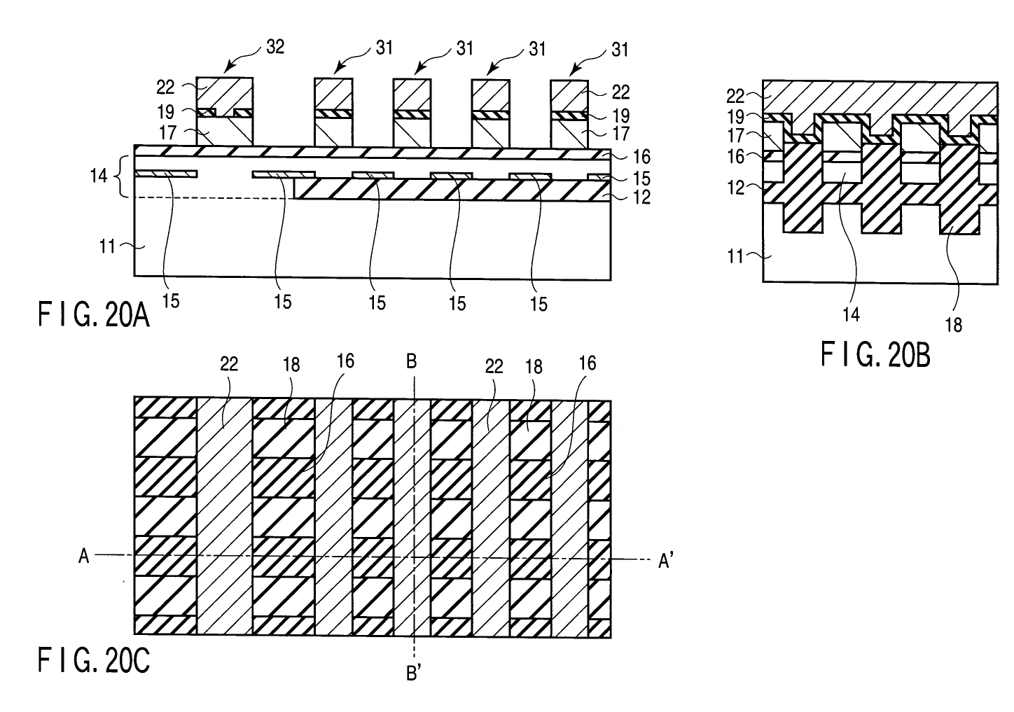

FIGS. 20A to 20C are views showing part of a method of manufacturing the semiconductor device shown in FIG. 19A and FIG. 19B. FIG. 20A is a cross-sectional view in a bit line direction. FIG. 20B is a cross-sectional view in a word line direction. FIG. 20C is a plan view. FIG. 20A corresponds to a cross section taken along the line A-A′ of FIG. 20C. FIG. 20B corresponds to a cross section taken along the line B-B′ of FIG. 20C.

According to this embodiment, ion implantation is not carried out to form the defect layer 15 in the process of FIGS. 3A to 3C of the first embodiment. In the process of FIGS. 6A to 6C of the first embodiment, the first gate structure 31 for a memory cell and the second gate structure 32 for a select transistor are formed. Thereafter, ion implantation is carried out to form the defect layer 15. As a result, as seen from FIGS. 20A to 20C, silicon ion is selectively implanted only to the region between a memory cell forming region and a select transistor forming region and to a region between adjacent select transistor forming regions. Thus, the defect layer 15 is formed based on ion-implanted excessive silicon (group IV element).

According to this embodiment, group IV element ions are implanted to form the defect layer 15 like the first embodiment. Thus, the same effect as the first embodiment is obtained. In particular, the defect layer 15 is formed at the region between a memory cell forming region and a select transistor forming region and at a region between adjacent select transistor forming regions. Therefore, it is possible to effectively extinguish carriers (electrons) transferred from the floating gate electrode film 17 to the single crystal silicon layer 14 by generation-recombination center of the defect layer 15 in an erase operation of a memory cell. As a result, this serves to prevent carriers from being stored in the single crystal silicon layer 14, and thus, to prevent memory cell characteristic from varying. In addition, according to this embodiment, the defect layer 15 is not formed under the first gate structure 31 for a memory cell and the second gate structure 32 for a select transistor. As a result, it is possible to prevent characteristic reduction of memory cell and select transistors based on the defect layer 15. Therefore, according to this embodiment, it is possible to prevent memory cell characteristic from being varied by storage of carriers. In addition, it is possible to prevent characteristic reduction of memory cell and select transistors, and thus, to obtain a nonvolatile semiconductor memory device, which is excellent in characteristic and reliability.

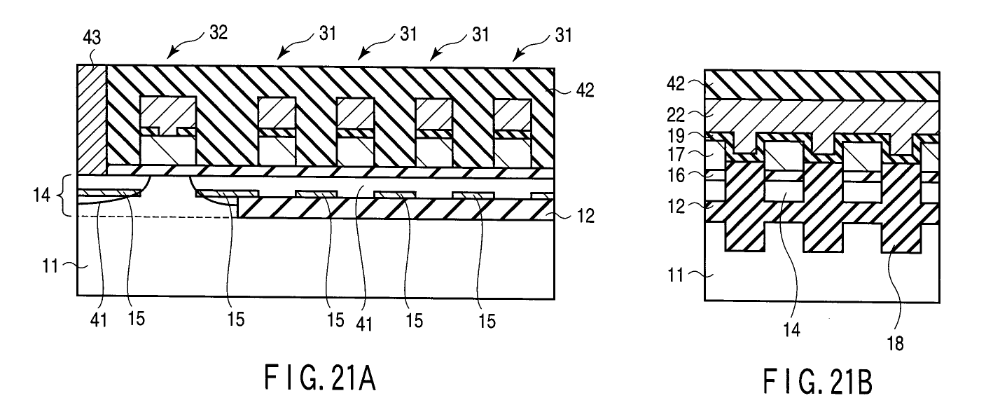

In this embodiment, an impurity diffusion layer 41 may be continuously connected as shown in FIG. 21A and FIG. 21B like the structure shown in FIG. 8A and FIG. 8B of the first embodiment. Even if the foregoing structure is provided, the same effect as above is obtained.

According to the foregoing first to fifth embodiments, the memory cell using the floating gate electrode as a charge storage layer has been described. The structure and method described in the foregoing embodiments are applicable to a MONOS memory cell using an insulating film such as silicon nitride film as a charge storage layer.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a single crystal silicon substrate:
an insulating layer partially formed on the single crystal silicon substrate;
a single crystal silicon layer formed on the single crystal silicon substrate and the insulating layer, and containing a defect layer resulting from an excessive group IV element; and
a plurality of first gate structures for memory cells, each including a first gate insulating film formed on the single crystal silicon layer, a charge storage layer formed on the first gate insulating film, a second gate insulating film formed on the charge storage layer, and a control gate electrode formed on the second gate insulating film.

2. The device according to claim 1, wherein at least part of the defect layer is formed at that portion of the single crystal silicon layer which is positioned on the insulating layer.

3. The device according to claim 1, further comprising:
a second gate structure for a select transistor, adjacent to the first gate structure, and including a gate insulating film formed on the single crystal silicon layer and a gate electrode formed on the gate insulating film.

4. The device according to claim 3, wherein the defect layer is not formed at that portion of the single crystal silicon layer which is positioned under the second gate structure.

5. The device according to claim 3, wherein the defect layer is formed below a region between the first and second gate structures.

6. The device according to claim 1, wherein the defect layer is formed below a region between first gate structures adjacent to each other.

7. The device according to claim 1, wherein the defect layer is formed at an interface between the insulating layer and the single crystal silicon layer.

8. The device according to claim 1, wherein the defect layer is formed at a position away from an interface between the insulating layer and the single crystal silicon layer.

9. The device according to claim 1, wherein the group IV element is selected from silicon and germanium.

10. The device according to claim 1, wherein the defect layer has a generation-recombination center of a carrier.

11. A method of manufacturing a semiconductor device, comprising:
partially forming an insulating layer on a single crystal silicon substrate;
forming an amorphous silicon layer on the single crystal silicon substrate and the insulating layer;
implanting a group IV element to the amorphous silicon layer;
annealing the amorphous silicon layer to which the group IV element is implanted, thereby forming a single crystal silicon layer containing a defect layer resulting from the group IV element;
forming a first gate insulating film on the single crystal silicon layer;
forming a charge storage layer on the first gate insulating film;
forming a second gate insulating film on the charge storage layer; and
forming a control gate electrode on the second gate insulating film.

12. The method according to claim 11, wherein a micro crystal grain contained in the amorphous silicon layer is destroyed by implanting the group IV element to the amorphous silicon layer.

13. The method according to claim 11, wherein the group IV element is selected from silicon and germanium.

14. A method of manufacturing a semiconductor device, comprising:
partially forming an insulating layer on a single crystal silicon substrate;
forming an amorphous silicon layer on the single crystal silicon substrate and the insulating layer;
implanting a group IV element to the amorphous silicon layer;
annealing the amorphous silicon layer to which the group IV element is implanted, thereby forming a preliminary single crystal silicon layer;
repeating implanting a group IV element to the preliminary single crystal silicon layer and annealing the preliminary single crystal silicon layer to which the group IV element is implanted one time or more, thereby forming a single crystal silicon layer containing a defect layer resulting from the group IV element;
forming a first gate insulating film on the single crystal silicon layer;
forming a charge storage layer on the first gate insulating film;
forming a second gate insulating film on the charge storage layer; and
forming a control gate electrode on the second gate insulating film.

15. The method according to claim 14, wherein a micro crystal grain contained in the amorphous silicon layer is destroyed by implanting the group IV element to the amorphous silicon layer.

16. The method according to claim 14, wherein the group IV element is selected from silicon and germanium.
